(19) United States
(12) Patent Application Publication
(10) Pub. No.: US 2024/0069450 A1
(43) Pub. Date: Feb. 29, 2024

(54) TRAINING MACHINE LEARNING MODELS BASED ON PARTIAL DATASETS FOR DEFECT LOCATION IDENTIFICATION

(71) Applicant: ASML Netherlands B.V., Veldhoven (NL)

(72) Inventors: Nabeel Noor MOIN, Fort Collins, CO (US); Chenxi LIN, Newark, CA (US); Yi ZOU, Foster City, CA (US)

(73) Assignee: ASML Netherlands B.V., Veldhoven (NL)

(21) Appl. No.: 18/267,734

(22) PCT Filed: Dec. 8, 2021
(86) PCT No.: PCT/EP2021/084841

§ 371 Date: Jun. 15, 2023

Related U.S. Application Data
(60) Provisional application No. 63/127,832, filed on Dec. 18, 2020.

(51) Int. Cl. G03F 7/00; G06N 20/20

(52) U.S. Cl. CPC G03F 7/7065; G03F 7/706841; G06N 20/20

(57) ABSTRACT

A method and apparatus for training a defect location prediction model to predict a defect for a substrate location is disclosed. A number of datasets having data regarding process-related parameters for each location on a set of substrates is received. Some of the locations have partial datasets in which data regarding one or more process-related parameters is absent. The datasets are processed to generate multiple parameter groups having data for different sets of process-related parameters. For each parameter group, a sub-model of the defect location prediction model is created based on the corresponding set of process-related parameters and trained using data from the parameter group. A trained sub-model(s) may be selected based on process-related parameters available in a candidate dataset and a defect prediction may be generated for a location associated with the candidate dataset using the selected sub-model.

### CROSS-REFERENCE TO RELATED APPLICATIONS

This application claims priority of U.S. application 63/127,832 which was filed on Dec. 18, 2020 and which is incorporated herein in its entirety by reference.

### TECHNICAL FIELD

The embodiments provided herein relate to semiconductor manufacturing, and more particularly to inspecting a semiconductor substrate.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important.

However, imaging resolution and throughput of inspection tools struggles to keep pace with the ever-decreasing feature size of IC components. The accuracy, resolution, and throughput of such inspection tools may be limited by defect detection methods used.

### SUMMARY

In some embodiments, there is provided a non-transitory computer-readable medium having instructions that, when executed by a computer, cause the computer to execute a method for training a defect location prediction model. The method includes: receiving a dataset for each of a set of locations on a set of substrates having data regarding a plurality of process-related parameters, wherein the set of locations comprise locations with partial datasets in which data regarding one or more of the process-related parameters is absent; processing the datasets to generate multiple parameter groups having different sets of process-related parameters, wherein each parameter group includes data for each parameter of a corresponding set of process-related parameters; and for each parameter group: creating a sub-model of the defect location prediction model based on the corresponding set of process-related parameters of the parameter group; and training the sub-model by using data from the parameter group.

In some embodiments, there is provided a non-transitory computer-readable medium having instructions that, when executed by a computer, cause the computer to execute a method for predicting a defect at a location on a substrate. The method includes: receiving a partial dataset for a location on a substrate, wherein the partial dataset includes data for a subset of a set of process-related parameters; selecting a first sub-model from a plurality of sub-models of a defect location prediction model trained to predict a defect associated with the location on the substrate, wherein the first sub-model is selected based on process-related parameters available in the partial dataset; and executing the selected sub-model to predict the defect.

In some embodiments, there is provided a method for training a defect location prediction model. The method includes: receiving a dataset for each of a set of locations on a set of substrates having data regarding a plurality of process-related parameters, wherein the set of locations comprise locations with partial datasets in which data regarding one or more of the process-related parameters is absent; processing the datasets to generate multiple parameter groups having different sets of process-related parameters, wherein each parameter group includes data for each parameter of a corresponding set of process-related parameters; and for each parameter group: creating a sub-model of the defect location prediction model based on the corresponding set of process-related parameters of the parameter group; and training the sub-model by using data from the parameter group.

In some embodiments, there is provided a method for predicting a defect at a location on a substrate. The method includes: receiving a partial dataset for a location on a substrate, wherein the partial dataset includes data for a subset of a set of process-related parameters; selecting a first sub-model from a plurality of sub-models of a defect location prediction model trained to predict a defect associated with the location on the substrate, wherein the first sub-model is selected based on process-related parameters available in the partial dataset; and executing the selected sub-model to predict the defect.

In some embodiments, there is provided an apparatus for for training a defect location prediction model. The apparatus includes: a memory storing a set of instructions; and at least one processor configured to execute the set of instructions to cause the apparatus to perform a method, which includes: receiving a dataset for each of a set of locations on a set of substrates having data regarding a plurality of process-related parameters, wherein the set of locations comprise locations with partial datasets in which data regarding one or more of the process-related parameters is absent; processing the datasets to generate multiple parameter groups having different sets of process-related parameters, wherein each parameter group includes data for each parameter of a corresponding set of process-related parameters; and for each parameter group: creating a sub-model of the defect location prediction model based on the corresponding set of process-related parameters of the parameter group; and training the sub-model by using data from the parameter group.

In some embodiments, a non-transitory computer readable medium that stores a set of instructions that is executable by at least one processor of a computing device to cause the computing device to perform a method discussed above.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an example electron beam inspection (EBI) system, consistent with embodiments of the present disclosure.

FIG. 2 is a schematic diagram illustrating an example electron beam tool that can be a part of the electron beam inspection system of FIG. 1, consistent with embodiments of the present disclosure.

FIG. 3 is a schematic diagram illustrating a semiconductor processing system, consistent with embodiments of the present disclosure.

FIG. 4 is a block diagram of a system for training of a defect location prediction model for predicting defective locations on a substrate, consistent with various embodiments of the present disclosure.

FIG. 5A is a block diagram for predicting defective locations on a substrate, consistent with embodiments of the present disclosure.

FIG. 5B is a block diagram for predicting defective locations on a substrate, consistent with embodiments of the present disclosure.

FIG. 6 is a flow diagram of a process for training a defect location prediction model to predict defective locations on a substrate, consistent with embodiments of the present disclosure.

FIG. 7 is a flow diagram of a process for predicting defective locations on a substrate using single-model prediction mode, consistent with embodiments of the present disclosure.

FIG. 8 is a flow diagram of a process for predicting defective locations on a substrate using multi-model prediction mode, consistent with embodiments of the present disclosure.

FIG. 9 is a block diagram that illustrates a computer system which can assist in implementing the methods, flows, modules, components, or the apparatus disclosed herein.

### DETAILED DESCRIPTION

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair. Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Inspecting a substrate is a resource intensive process and inspecting all locations on the substrate may not only consume significant computing resources, but also time. For example, it may a number of days to inspect an entire substrate. One of the ways to make the inspection process more efficient (e.g., minimize the resources consumed) is to identify locations on the substrate that are more likely to have a defect and inspect only those identified locations instead of all locations. For example, prior methods used a machine learning (ML) model to predict locations that are more likely to have a defect. The ML models are trained using process-related datasets, each of which has data for a number of process-related parameters of various processes (e.g., metrology data) involved in forming a pattern on a substrate. The ML model predicts whether a location on the substrate is having a defect or not based on process-related dataset of a given substrate. However, the prior methods have some drawbacks. The prediction accuracy of such ML models depends on a completeness of the process-related dataset available for training the ML model and often some of the data may be missing for some substrates or for some locations on a substrate. Such incomplete datasets with missing values may neither be used to train the ML model nor would the ML model be able to make predictions on datasets with missing values. In order to overcome such missing data problems, some methods remove all partial process-related datasets (e.g., a dataset in which values for at least some process-related parameters are missing or absent) from the training dataset used for training the ML model, which causes information loss, and may result in inaccurate prediction of results thereby rendering the ML model less useful. Some other methods extrapolate the available data to determine the missing data and use the extrapolated data for the training. However, the prediction results of even such ML models are also not accurate. These and other drawbacks exist.

Embodiments of the present disclosure discuss a defect location prediction model that may be trained using all available process-related datasets (“datasets”), including partial datasets and full or complete datasets, for predicting a defective location on a substrate. By not deleting the partial datasets from the training dataset and using all available datasets (e.g., the partial datasets in addition to complete datasets), the information loss in training the defect location prediction model is minimized and therefore, an accuracy of prediction is also improved. Further, since all available datasets are considered, a model coverage of the defect location prediction model also improves, that is, the ability of the defect location prediction model to generate a prediction for a broad range of datasets, may also be improved. The embodiments process the datasets available for training (e.g., process-related datasets of a set of locations on a set of substrates) to identify various process-related parameter groups (“parameter groups”) in which each group has different process-related parameters (“parameters”). In some embodiments, if the number of parameters in a complete dataset is n, then the number of parameter groups may be 2n−1. For example, a first parameter group may correspond to two parameters—“A” and “B” of a number of parameters (e.g., A-J) available in a complete dataset, a second parameter group may correspond to three parameters—“A,” “B” and “D”, a third parameter group may correspond to one parameter—“A,” and so on. Each parameter group is populated with data for the corresponding parameters from all the datasets that have data for those parameters. A sub-model is generated for each of the parameter groups and is trained with the dataset from the corresponding group. For example, the sub-model corresponding to the first parameter group is trained with the dataset having values of parameters “A” and “B.” When a new dataset (e.g., partial or complete) associated with a location of a substrate is input to the defect location prediction model, the defect location prediction model may choose one or more of the sub-models based on the available parameters in the new dataset and execute the selected sub-model(s) for generating the prediction. For example, if the new dataset is a partial dataset that has data for only some of the parameters (e.g., “A” and “B”), the defect location prediction model may choose a sub-model corresponding to the parameter group “A” and “B” (e.g., first parameter group) to generate the prediction of a defective location based on the values of parameters “A” and “B.” By training and using different sub-models for different parameter combinations, the defect location prediction model may be capable of generating predictions based on partial datasets.

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

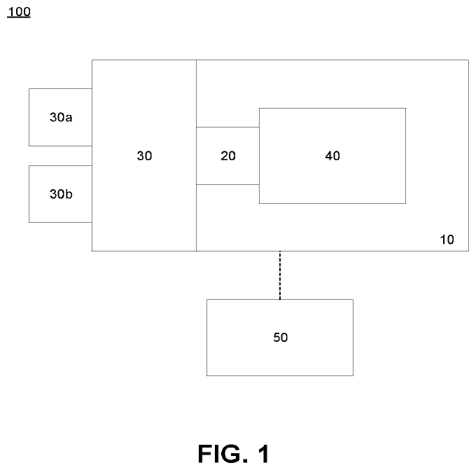

Reference is now made to FIG. 1, which illustrates an example electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

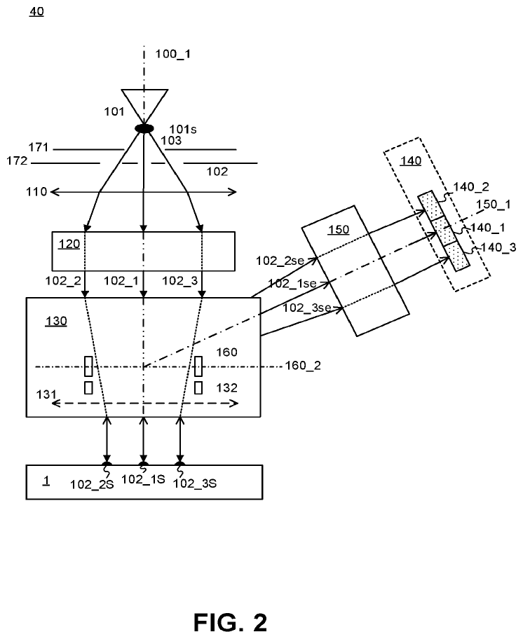

Reference is now made to FIG. 2, which illustrates a schematic diagram illustrating an example electron beam tool 40 that can be a part of the example charged particle beam inspection system 100 of FIG. 1, consistent with embodiments of the present disclosure. An electron beam tool 40 (also referred to herein as apparatus 40) comprises an electron source 101, a gun aperture plate 171 with a gun aperture 103, a pre-beamlet forming mechanism 172, a condenser lens 110, a source conversion unit 120, a primary projection optical system 130, a sample stage (not shown in FIG. 2), a secondary imaging system 150, and an electron detection device 140. Primary projection optical system 130 can comprise an objective lens 131. Electron detection device 140 can comprise a plurality of detection elements 1401, 1402, and 140_3. Beam separator 160 and deflection scanning unit 132 can be placed inside primary projection optical system 130. It may be appreciated that other commonly known components of apparatus 40 may be added/omitted as appropriate.

Electron source 101, gun aperture plate 171, condenser lens 110, source conversion unit 120, beam separator 160, deflection scanning unit 132, and primary projection optical system 130 can be aligned with a primary optical axis 100_1 of apparatus 100. Secondary imaging system 150 and electron detection device 140 can be aligned with a secondary optical axis 150_1 of apparatus 40.

Electron source 101 can comprise a cathode, an extractor or an anode, wherein primary electrons can be emitted from the cathode and extracted or accelerated to form a primary electron beam 102 that forms a crossover (virtual or real) 101s. Primary electron beam 102 can be visualized as being emitted from crossover 101s.

Source conversion unit 120 may comprise an image-forming element array (not shown in FIG. 2), an aberration compensator array (not shown), a beam-limit aperture array (not shown), and a pre-bending micro-deflector array (not shown). The image-forming element array can comprise a plurality of micro-deflectors or micro-lenses to form a plurality of parallel images (virtual or real) of crossover 101s with a plurality of beamlets of primary electron beam 102. FIG. 2 shows three beamlets 1021, 1022, and 1023 as an example, and it is appreciated that the source conversion unit 120 can handle any number of beamlets.

In some embodiments, source conversion unit 120 may be provided with beam-limit aperture array and image-forming element array (both are not shown). The beam-limit aperture array may comprise beam-limit apertures. It is appreciated that any number of apertures may be used, as appropriate. Beam-limit apertures may be configured to limit sizes of beamlets 1021, 102_2, and 102_3 of primary electron beam 102. The image-forming element array may comprise image-forming deflectors (not shown) configured to deflect beamlets 1021, 1022, and 102_3 by varying angles towards primary optical axis 100_1. In some embodiments, deflectors further away from primary optical axis 100_1 may deflect beamlets to a greater extent. Furthermore, image-forming element array may comprise multiple layers (not illustrated), and deflectors may be provided in separate layers. Deflectors may be configured to be individually controlled independent from one another. In some embodiments, a deflector may be controlled to adjust a pitch of probe spots (e.g., 102_1S, 102_2S, and 1023S) formed on a surface of sample 1. As referred to herein, pitch of the probe spots may be defined as the distance between two immediately adjacent probe spots on the surface of sample 1.

A centrally located deflector of image-forming element array may be aligned with primary optical axis 100_1 of electron beam tool 40. Thus, in some embodiments, a central deflector may be configured to maintain the trajectory of beamlet 102_1 to be straight. In some embodiments, the central deflector may be omitted. However, in some embodiments, primary electron source 101 may not necessarily be aligned with the center of source conversion unit 120. Furthermore, it is appreciated that while FIG. 2 shows a side view of apparatus 40 where beamlet 1021 is on primary optical axis 1001, beamlet 102_1 may be off primary optical axis 100_1 when viewed from a different side. That is, in some embodiments, all of beamlets 1021, 1022, and 102_3 may be off-axis. An off-axis component may be offset relative to primary optical axis 100_1.

The deflection angles of the deflected beamlets may be set based on one or more criteria. In some embodiments, deflectors may deflect off-axis beamlets radially outward or away (not illustrated) from primary optical axis 100_1. In some embodiments, deflectors may be configured to deflect off-axis beamlets radially inward or towards primary optical axis 1001. Deflection angles of the beamlets may be set so that beamlets 102_1, 1022, and 1023 land perpendicularly on sample 1. Off-axis aberrations of images due to lenses, such as objective lens 131, may be reduced by adjusting paths of the beamlets passing through the lenses. Therefore, deflection angles of off-axis beamlets 102_2 and 1023 may be set so that probe spots 102_2S and 102_3S have small aberrations. Beamlets may be deflected so as to pass through or close to the front focal point of objective lens 131 to decrease aberrations of off-axis probe spots 1022S and 102_3S. In some embodiments, deflectors may be set to make beamlets 1021, 1022, and 102_3 land perpendicularly on sample 1 while probe spots 102_1S, 102_2S, and 102_3S have small aberrations.

Condenser lens 110 is configured to focus primary electron beam 102. The electric currents of beamlets 1021, 102_2, and 102_3 downstream of source conversion unit 120 can be varied by adjusting the focusing power of condenser lens 110 or by changing the radial sizes of the corresponding beam-limit apertures within the beam-limit aperture array. The electric currents may be changed by both, altering the radial sizes of beam-limit apertures and the focusing power of condenser lens 110. Condenser lens 110 may be an adjustable condenser lens that may be configured so that the position of its first principle plane is movable. The adjustable condenser lens may be configured to be magnetic, which may result in off-axis beamlets 102_2 and 102_3 illuminating source conversion unit 120 with rotation angles. The rotation angles may change with the focusing power or the position of the first principal plane of the adjustable condenser lens. Accordingly, condenser lens 110 may be an anti-rotation condenser lens that may be configured to keep the rotation angles unchanged while the focusing power of condenser lens 110 is changed. In some embodiments, condenser lens 110 may be an adjustable anti-rotation condenser lens, in which the rotation angles do not change when the focusing power and the position of the first principal plane of condenser lens 110 are varied.

Electron beam tool 40 may comprise pre-beamlet forming mechanism 172. In some embodiments, electron source 101 may be configured to emit primary electrons and form a primary electron beam 102. In some embodiments, gun aperture plate 171 may be configured to block off peripheral electrons of primary electron beam 102 to reduce the Coulomb effect. In some embodiments, pre-beamlet-forming mechanism 172 further cuts the peripheral electrons of primary electron beam 102 to further reduce the Coulomb effect. Primary electron beam 102 may be trimmed into three primary electron beamlets 1021, 1022, and 1023 (or any other number of beamlets) after passing through pre-beamlet forming mechanism 172. Electron source 101, gun aperture plate 171, pre-beamlet forming mechanism 172, and condenser lens 110 may be aligned with a primary optical axis 100_1 of electron beam tool 40.

Pre-beamlet forming mechanism 172 may comprise a Coulomb aperture array. A center aperture, also referred to herein as the on-axis aperture, of pre-beamlet-forming mechanism 172 and a central deflector of source conversion unit 120 may be aligned with primary optical axis 100_1 of electron beam tool 40. Pre-beamlet-forming mechanism 172 may be provided with a plurality of pre-trimming apertures (e.g., a Coulomb aperture array). In FIG. 2, the three beamlets 1021, 102_2 and 1023 are generated when primary electron beam 102 passes through the three pre-trimming apertures, and much of the remaining part of primary electron beam 102 is cut off. That is, pre-beamlet-forming mechanism 172 may trim much or most of the electrons from primary electron beam 102 that do not form the three beamlets 1021, 102_2 and 102_3. Pre-beamlet-forming mechanism 172 may cut off electrons that will ultimately not be used to form probe spots 102_1S, 102_2S and 102_3S before primary electron beam 102 enters source conversion unit 120. In some embodiments, a gun aperture plate 171 may be provided close to electron source 101 to cut off electrons at an early stage, while pre-beamlet forming mechanism 172 may also be provided to further cut off electrons around a plurality of beamlets. Although FIG. 2 demonstrates three apertures of pre-beamlet forming mechanism 172, it is appreciated that there may be any number of apertures, as appropriate.

In some embodiments, pre-beamlet forming mechanism 172 may be placed below condenser lens 110. Placing pre-beamlet forming mechanism 172 closer to electron source 101 may more effectively reduce the Coulomb effect. In some embodiments, gun aperture plate 171 may be omitted when pre-beamlet forming mechanism 172 is able to be located sufficiently close to source 101 while still being manufacturable.

Objective lens 131 may be configured to focus beamlets 1021, 1022, and 102_3 onto a sample 1 for inspection and can form three probe spots 102_1s, 102_2s, and 102_3s on surface of sample 1. Gun aperture plate 171 can block off peripheral electrons of primary electron beam 102 not in use to reduce Coulomb interaction effects. Coulomb interaction effects can enlarge the size of each of probe spots 102_1s, 102_2s, and 102_3s, and therefore deteriorate inspection resolution.

Beam separator 160 may be a beam separator of Wien filter type comprising an electrostatic deflector generating an electrostatic dipole field E1 and a magnetic dipole field B1 (both of which are not shown in FIG. 2). If they are applied, the force exerted by electrostatic dipole field E1 on an electron of beamlets 102_1, 1022, and 102_3 is equal in magnitude and opposite in direction to the force exerted on the electron by magnetic dipole field B1. Beamlets 1021, 1022, and 102_3 can therefore pass straight through beam separator 160 with zero deflection angles.

Deflection scanning unit 132 can deflect beamlets 1021, 1022, and 102_3 to scan probe spots 102_1s, 102_2s, and 102_3s over three small scanned areas in a section of the surface of sample 1. In response to incidence of beamlets 102_1, 1022, and 1023 at probe spots 102_1s, 102_2s, and 102_3s, three secondary electron beams 102_1se, 102_2se, and 102_3se may be emitted from sample 1. Each of secondary electron beams 102_1se, 102_2se, and 102_3se can comprise electrons with a distribution of energies including secondary electrons (energies≤50 eV) and backscattered electrons (energies between 50 eV and landing energies of beamlets 102_1, 1022, and 102_3). Beam separator 160 can direct secondary electron beams 102_1se, 102_2se, and 102_3se towards secondary imaging system 150. Secondary imaging system 150 can focus secondary electron beams 102_1se, 102_2se, and 102_3se onto detection elements 1401, 1402, and 1403 of electron detection device 140. Detection elements 1401, 1402, and 140_3 can detect corresponding secondary electron beams 102_1se, 102_2se, and 102_3se and generate corresponding signals used to construct images of the corresponding scanned areas of sample 1.

In FIG. 2, three secondary electron beams 102_1se, 102_2se, and 102_3se respectively generated by three probe spots 102_1S, 102_2S, and 102_3S, travel upward towards electron source 101 along primary optical axis 100_1, pass through objective lens 131 and deflection scanning unit 132 in succession. The three secondary electron beams 102_1se, 102_2se and 102_3se are diverted by beam separator 160 (such as a Wien Filter) to enter secondary imaging system 150 along secondary optical axis 150_1 thereof. Secondary imaging system 150 focuses the three secondary electron beams 102_1se˜102_3se onto electron detection device 140 which comprises three detection elements 1401, 1402, and 140_3. Therefore, electron detection device 140 can simultaneously generate the images of the three scanned regions scanned by the three probe spots 1021S, 1022S and 102_3S, respectively. In some embodiments, electron detection device 140 and secondary imaging system 150 form one detection unit (not shown). In some embodiments, the electron optics elements on the paths of secondary electron beams such as, but not limited to, objective lens 131, deflection scanning unit 132, beam separator 160, secondary imaging system 150 and electron detection device 140, may form one detection system.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 140 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 140 and may construct an image. The image acquirer may thus acquire images of sample 1. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on one or more imaging signals received from electron detection device 140. An imaging signal may correspond to a scanning operation for conducting charged particle imaging. An acquired image may be a single image comprising a plurality of imaging areas or may involve multiple images. The single image may be stored in the storage. The single image may be an original image that may be divided into a plurality of regions. Each of the regions may comprise one imaging area containing a feature of sample 1. The acquired images may comprise multiple images of a single imaging area of sample 1 sampled multiple times over a time sequence or may comprise multiple images of different imaging areas of sample 1. The multiple images may be stored in the storage. In some embodiments, controller 50 may be configured to perform image processing steps with the multiple images of the same location of sample 1.

In some embodiments, controller 50 may include measurement circuitries (e.g., analog-to-digital converters) to obtain a distribution of the detected secondary electrons. The electron distribution data collected during a detection time window, in combination with corresponding scan path data of each of primary beamlets 102_1, 1022, and 102_3 incident on the wafer surface, can be used to reconstruct images of the wafer structures under inspection. The reconstructed images can be used to reveal various features of the internal or external structures of sample 1, and thereby can be used to reveal any defects that may exist in the wafer.

In some embodiments, controller 50 may control a motorized stage (not shown) to move sample 1 during inspection. In some embodiments, controller 50 may enable the motorized stage to move sample 1 in a direction continuously at a constant speed. In other embodiments, controller 50 may enable the motorized stage to change the speed of the movement of sample 1 over time depending on the steps of scanning process. In some embodiments, controller 50 may adjust a configuration of primary projection optical system 130 or secondary imaging system 150 based on images of secondary electron beams 102_1se, 102_2se, and 102_3se.

Although FIG. 2 shows that electron beam tool 40 uses three primary electron beams, it is appreciated that electron beam tool 40 may use two or more number of primary electron beams. The present disclosure does not limit the number of primary electron beams used in apparatus 40.

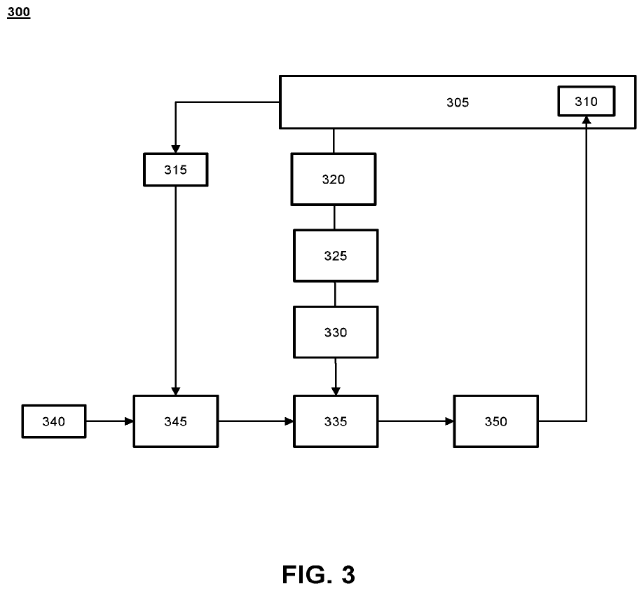

Reference is now made to FIG. 3, which is a schematic diagram illustrating a semiconductor processing system. FIG. 3 illustrates a conventional semiconductor processing system 300 having a scanner 305, a development tool 320, an etching tool 325, an ash tool 330, a monitoring tool 335, a point determination tool 345, and a verification unit 350. The scanner 305 may include a control unit 310. The semiconductor processing system 300 may aid in a computer guided inspection of a substrate, as described below.

The scanner 305 may expose a substrate coated with photoresist to a circuit pattern to be transferred to the substrate. The control unit 310 may control an exposure recipe used to expose the substrate. The control unit 310 may adjust various exposure recipe parameters, for example, exposure time, source intensity, and exposure dose. A high-density focus map (HDFM) 315 may be recorded corresponding to the exposure.

The development tool 320 may develop the pattern on the exposed substrate by removing the photoresist from unwanted regions. For a positive photoresist, the portion of the photoresist that is exposed to light in scanner 305 becomes soluble to the photoresist developer and the unexposed portion of the photoresist remains insoluble to the photoresist developer. For a negative photoresist, the portion of the photoresist that is exposed to light in scanner 305 becomes insoluble to the photoresist developer and the unexposed portion of the photoresist remains soluble to the photoresist developer.

The etching tool 325 may transfer the pattern to one or more films under the photoresist by etching the films from portions of the substrate where the photoresist has been removed. Etching tool 325 can be a dry etch or wet etch tool.

The ash tool 330 can remove the remaining photoresist from the etched substrate and the pattern transfer process to the film on the substrate can be completed.

The monitoring tool 335 may inspect the processed substrate at one or more locations on the substrate to generate monitor results. The monitor results may be based on spatial pattern determination, size measurement of different pattern features or a positional shift in different pattern features. The inspection locations can be determined by the point determination tool 345. In some embodiments, the monitoring tool is part of the EBI system 100 of FIG. 1 or may be the electron beam tool 40.

The point determination tool 345 may include one or more prediction models to determine the inspection locations on the substrate based on the HDFM 315 and weak point information 340. In some embodiments, the point determination tool 345 may generate a prediction for each of the locations on the substrate that predicts a likelihood of the location being a defective (or non-defective) location. For example, the point determination tool 345 may assign a probability value to each of the locations that indicates a probability that the location is a defective (or non-defective) location.

The weak point information 340 may include information regarding locations with a high probability of problems related to the patterning process. The weak point information 340 may be based on the transferred pattern, various process parameters and properties of the wafer, scanner 305, or etching tool 325.

The verification unit 350 may compare the monitor results from monitoring tool 335 with corresponding design parameters to generate verified results. The verification unit 350 may provide the verified results to the control unit 310 of scanner 305. The control unit 310 may adjust the exposure recipe for subsequent substrates based on the verified results. For example, the control unit 310 may decrease exposure dose of scanner 305 for some locations on subsequent substrates based on the verified results.

While the foregoing description describes the semiconductor processing system 300 as having the scanner 305, the development tool 320, the etching tool 325, the ash tool 330, the semiconductor processing system 300 is not restricted to the foregoing tools and may have additional tools that aid in printing a pattern on the substrate. In some embodiments, two or more tools may be combined to form a composite tool that provides functionalities of multiple tools. Additional details with respect to the semiconductor processing system 300 may be found in U.S. Patent Publication No. 2019/0187670, which is incorporated by reference in its entirety.

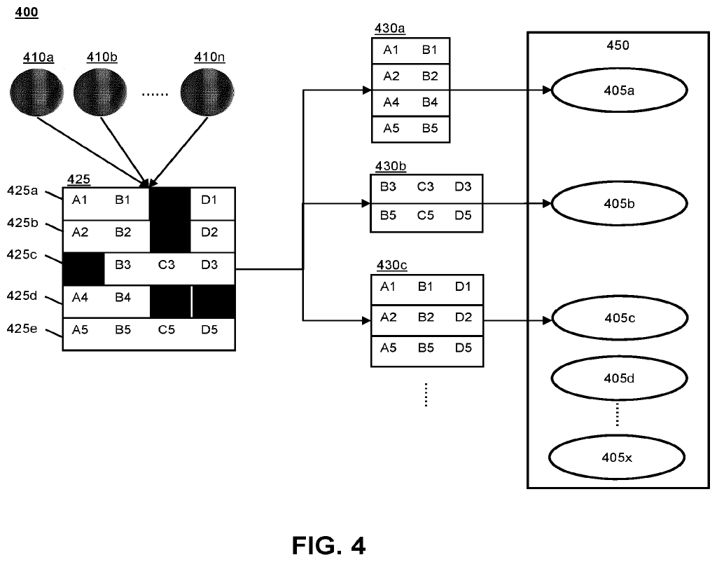

The following paragraphs describe a defect location prediction model that predicts defective locations on a substrate even when an input process-related dataset has partial data (e.g., data for one or more process-related parameters that is otherwise available in a complete dataset may be absent). The defect location prediction model may include a library of sub-models each configured to generate a prediction (e.g., whether a location on a substrate is defective or not) based on a unique set of process-related parameters. When a new dataset (e.g., partial or complete) is input to the defect location prediction model, the defect location prediction model may select one or more of the sub-models that match the process-related parameters in the new dataset and execute the selected sub-model(s) to generate the prediction. The training of the defect location prediction model and prediction of the defect locations using the trained defect location prediction model are described at least with reference to FIGS. 4-8 below.

FIG. 4 is a block diagram of a system 400 for training of a defect location prediction model 450 for predicting defective locations on a substrate, consistent with various embodiments of the present disclosure. In some embodiments, the defect location prediction model 450 includes one or more machine learning (ML) models (e.g., sub-models 405a-405x) and is similar to the point determination tool 345 of FIG. 3. The defect location prediction model 450 may generate a prediction indicating whether a location on a substrate is likely a defective location or a non-defective location. For example, a prediction for a “location a” on a substrate may include a likelihood of whether the “location a” is a defective location or a non-defective location. For example, the prediction may include a probability of “0.8,” which indicates that there is a “80%” likelihood that the “location a” has a defect and “20%” likelihood that the “location a” does not have a defect. Accordingly, the defect location prediction model 450 may classify the “location a” as a defective location. Other types of classification techniques, which do not use probability values, may be used to classify the locations into defective locations and non-defective locations.

In some embodiments, the defect location prediction model 450 generates the prediction based on a process-related dataset (“dataset”) associated with a location on a substrate. The dataset may include data (e.g., values) of one or more process-related parameters associated with various tools and processes of the semiconductor processing system 300 such as the development tool 320, the etching tool 325, the ash tool 330, or other processes. For example, the process-related parameters may include metrology data such as critical dimension (CD), aberrations, edge placement errors (EPE), thickness of film on a substrate, or other such parameters that may contribute to a defect. A dataset may include data (e.g., values) of one or more process-related parameters for a location on a substrate. For example, as illustrated in FIG. 4, a first dataset 425a associated with a first location on a first substrate 410a includes data (e.g., “A1,” “B1,” “D1”) for process-related parameters “A” (e.g., CD), “B” (e.g., EPE) and “D” (e.g., thickness of film), and a fifth dataset 425e associated with a second location on the first substrate 410a or another substrate (e.g., second substrate 410b) includes data (e.g., “A1,” “B1,” “CI,” “D1”) for process-related parameters “A” (e.g., CD), “B” (e.g., EPE) “C,” (e.g., local CD uniformity) and “D” (e.g., thickness of film).

In some embodiments, a complete dataset has data for n process-related parameters, where “n” may be a user-defined number. A partial dataset may be a dataset that has data for less than n process-related parameters. For example, if n=4, then the fifth dataset 425e, which has data for all n process-related parameters “A, “B,” “C,” and “D”, may be considered as a complete or full dataset, and the datasets which do not have data for at least one of the n process-related parameters, such as datasets 425a-425d, may be considered as partial datasets.

In some embodiments, to generate a prediction for an input dataset that is partial, the defect location prediction model 450 may have to be trained using partial datasets (including any complete datasets) to generate such predictions. In some embodiments, the defect location prediction model 450 is trained using a training dataset 425, which has datasets for a number of locations of a number of substrates 410a-410n of which at least some datasets are partial datasets. For example, as described above, the datasets 425a-425d from the training dataset 425 may be considered as partial datasets. The training dataset 425 is processed to determine a number of parameter groups in which each parameter group has a unique set of parameters. In some embodiments, if the number of parameters in a complete dataset is n, then the number of parameter groups that may be formed is x=2n−1. That is, if n=4, “15” unique parameter groups may be formed of which five parameter groups are illustrated in FIG. 4. For example, a first parameter group 430a may correspond to two parameters—“A” and “B” of the complete set of parameters (e.g., A-D), a second parameter group 430b may correspond to three parameters—“B,” “C,” and “D,” a third parameter group 430c may correspond to three parameters—“A,” “B” and “D,” a fourth parameter group may correspond to one parameter—“A” and so on. After identifying the parameter groups, each parameter group is populated with data for the corresponding parameters from all the datasets that have data for those parameters. For example, the first parameter group 430a is populated with data for parameters “A” and “B” from all the datasets in the training dataset 425 and the datasets that do not have data for those parameters are deleted or excluded from the first parameter group 430a (e.g., dataset 425c). In other words, the first parameter group 430a is populated with data for parameters “A” and “B” from all the datasets in the training dataset 425 that have data for those parameters.

The defect location prediction model 450 may include a library of sub-models each configured to generate a prediction for a unique set of process-related parameters. In some embodiments, each sub-model may be a ML model and may be similar to the point determination tool 345 of FIG. 3. A sub-model is generated for each of the parameter groups and is trained with the dataset from the corresponding parameter group. For example, a first sub-model 405a corresponding to the first parameter group 430a is trained with the dataset (e.g., having values of parameters “A” and “B”) of the first parameter group 430a. In some embodiments, the training dataset 425 may be a labeled dataset, which includes the data for the process-related parameters and actual inspection results of the locations of substrates. For example, for a location “a” on the first substrate 410a, the dataset 425a may include data of process-related parameters “A1,” “B1,” “D1,” and actual result associated with the location “a” as “defective.” The first sub-model 405a generates a predicted result based on the input dataset (e.g., dataset having values “A1” and “B1”) of the first parameter group 430a. The first sub-model 405a then compares the predicted results with the actual results to determine a cost function of the first sub-model 405a, which may be indicative of a deviation between the predicted results and the actual inspection results. The first sub-model 405a may update its configurations (e.g., weights, biases, or other model parameters of the first sub-model 405a) based on the cost function or other reference feedback information (e.g., user indication of accuracy, reference labels, or other information) to reduce the cost function. The above process is repeated iteratively with additional datasets and associated actual results from the first parameter group 430a in each iteration until a termination condition is satisfied. The termination condition may include a predefined number of iterations, the cost function being minimized, the cost function not reducing at a rate above a specified threshold, or other such conditions. After the termination condition is satisfied, the first sub-model 405a may be considered to be “trained” and may be used for identifying or predicting defective locations in a new substrate (e.g., a substrate that has not been analyzed using the defect location prediction model 450 yet).

Similarly, other sub-models 405b-x, where x is the total number of parameter groups, are generated for other parameter groups and trained with datasets from the corresponding parameter groups. For example, a second sub-model 405b may be trained using the datasets from the second parameter group 430b and a third sub-model 405c may be trained using the datasets from the third parameter group 430c.

In some embodiments, a selected set of sub-models may be generated instead of generating a sub-model for each of the x parameter groups. For example, the sub-models may not be generated for those parameter groups having parameters for which a candidate dataset may not typically include data. Continuing with the example, if candidate datasets for which the predictions are to be made do not typically include data for parameter “C”, then the sub-models corresponding to parameter groups that include the parameter “C” may not be generated, thereby minimizing the computing resources that may be consumed in generating or training those sub-models. In some embodiments, a ML model may be used to identify the parameter groups (e.g., based on parameters in candidate datasets for which predictions were generated previously) for which the sub-models are to be generated. In another example, the sub-models may be generated only for user-selected parameter groups.

In some embodiments, a sub-model may be trained using another trained sub-model instead training from the beginning, thereby minimizing the time or computing resources that may be consumed in training the sub-model. For example, a trained first sub-model 405a corresponding to parameters “A” and “B” may be used to train any sub-model corresponding to a parameter group having one or more parameters in addition to all the parameters of the first sub-model 405a, such as the third sub-model 405c corresponding to parameters “A” “B,” “C”. In some embodiments, model information (e.g., weights, biases, or other information) of a trained sub-model may be reused in training another untrained sub-model. For example, weights or biases of the first sub-model 405a may be used for initializing the weights or biases corresponding to inputs A and B in the untrained third sub-model 405c. In some embodiments, the first sub-model 405a is used to train the third sub-model 405c based on an assumption that the trained first and third sub-models may have a similar output dependence on inputs A and B, so the third sub-model 405c initialized based on the first sub-model 405a may take less time to reach its final trained state in comparison to being trained from the beginning (e.g., with uninitialized values for weights, biases, or other information).

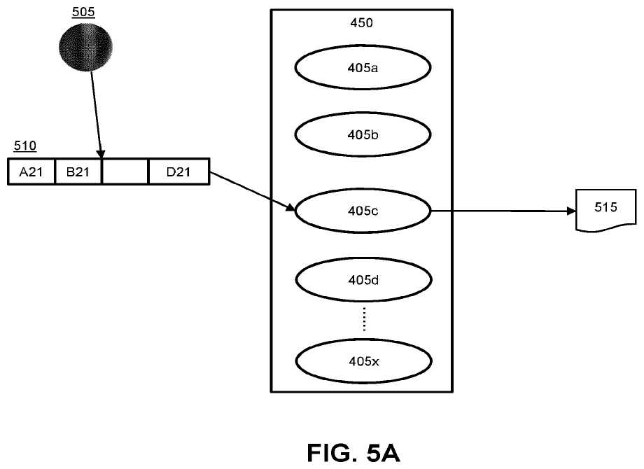

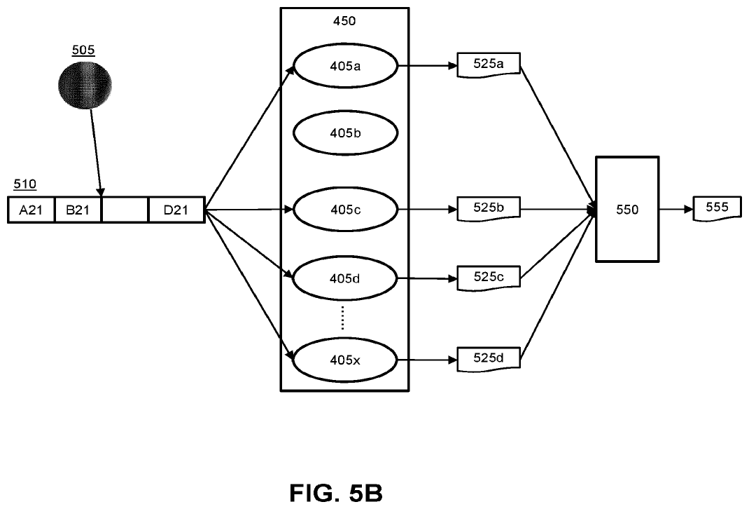

FIG. 5A is a block diagram for predicting defective locations on a substrate 505, consistent with embodiments of the present disclosure. The defect location prediction model 450 may be used to predict defective locations on any given substrate after the defect location prediction model 450 is trained (e.g., as described above at least with reference to FIG. 4). For example, an input dataset 510 associated with a specified location on the substrate 505 may be input to the defect location prediction model 450 to generate a prediction for the specified location. The defect location prediction model 450 may select one of the sub-models 405 based on the parameters available in the input dataset 510. In some embodiments, the defect location prediction model 450 may select one of the sub-models 405 corresponding to a parameter group that matches with the parameters available in the input dataset 510. The input dataset 510 is a partial dataset that includes parameters “A” “B” and “D,” so the defect location prediction model 450 may select a third sub-model 405c corresponding to the third parameter group 430c, which includes parameters “A” “B” and “D”. The third sub-model 405c is then executed with the values “A21” “B21” and “D21” to generate a prediction 515 for the specified location. The prediction 515 may indicate whether the specified location is likely to be defective or non-defective. While the input dataset 510 is illustrated as a partial dataset, the defect location prediction model 450 is not limited to generating predictions based on partial datasets, the defect location prediction model 450 may generate predictions based on complete datasets as well.

FIG. 5B is a block diagram for predicting defective locations on a substrate 505, consistent with embodiments of the present disclosure. In some embodiments, the defect location prediction model 450 may use more than one sub-model to generate a prediction. For example, the defect location prediction model 450 may use sub-models corresponding to various combinations of the parameters available in the input dataset 510. The input dataset 510 includes parameters “A,” “B,” and “D,” so the defect location prediction model 450 may select a first sub-model 405a corresponding to the first parameter group 430a, which includes parameters “A” and “B,” a third sub-model 405c corresponding to the third parameter group 430c, which includes parameters “A,” “B,” and “D,” a fourth sub-model 405d corresponding to a fourth parameter group, which includes parameters “B” and “D,” and a fifth sub-model 405x corresponding to a fifth parameter group, which includes parameters “A” and “D” and so on. Each of the selected sub-models 405 is then executed with the values of the corresponding parameters to generate a prediction for the specified location. Each of the predictions 525a-d from the selected sub-models are then input to an ensemble model 550, which generates a final prediction 555 that indicates whether the specified location is likely to be defective or non-defective. The ensemble model 550 may generate the final prediction 555 in a number of ways. For example, the ensemble model 550 may be a ML model that is trained to generate a final prediction based on predictions input from one or more sub-models. In another example, the ensemble model 550 may be programmed to assign different weights to predictions from different sub-models and determine the final prediction 555 as a function of the weighted predictions.

The defect location prediction model 450 may be used in “single-model” prediction mode in which one of many sub-models is used to generate the prediction (e.g., as described with reference to FIG. 5A), or may be used in “multi-model” prediction mode in which two or more sub-models are used to generate the prediction (e.g., as described with reference to FIG. 5B). In some embodiments, using the multi-model prediction mode may require generation and training of various sub-models, e.g., sub-models corresponding to various combinations of parameters available in an input dataset, which may consume significant amount of time and computing resources. However, in some cases, the multi-model prediction mode may generate a prediction with greater accuracy than the single-model prediction mode. In some embodiments, using the single-model prediction mode may require generation and training of lesser number of sub-models than required in multi-model prediction mode, thereby minimizing the time and computing resources consumed in generating and training the sub-models. For example, if the input datasets typically have data for process-related parameters “A” “B” and “D” or “B” “C” and “D”, then two sub-models, one corresponding to parameter set “A” “B” and “D” and another one corresponding to “B” “C” and “D” are all that may be required in single-model prediction mode as opposed to significantly more (e.g., “23−1=7”) in multi-model prediction mode. In yet another example, if the set of process-related parameters that may typically be expected in input datasets is not known or it varies significantly between input datasets, then all 2N−1 sub-models may have to be trained for using the single-model prediction mode, whereas a significantly lesser number of sub-models may be trained (e.g., for selected combinations of process-related parameters such as AB, AC, BC, etc.) for using the multi-model prediction mode.

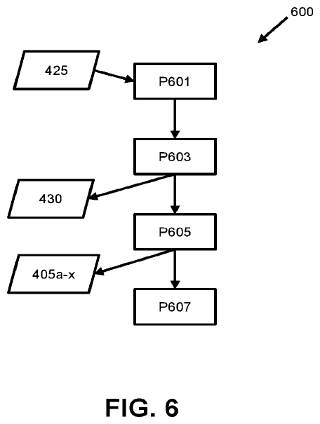

FIG. 6 is a flow diagram of a process 600 for training a defect location prediction model to predict defective locations on a substrate, consistent with embodiments of the present disclosure. In some embodiments, the process 600 may be implemented in the system 400 of FIG. 4. In operation P601, a training dataset 425 is received. In some embodiments, the training dataset 425 may be a labeled dataset, which includes data for process-related parameters and actual inspection results of a number of locations of a number of substrates. For example, for a location “a” on the first substrate 410a, the first dataset 425a may include data of process-related parameters (e.g., “A1,” “B1,” “D1,” which can be metrology data for the location “a” such as CD, EPE, thickness of resist on the first substrate 410a) and actual inspection result (not illustrated) associated with the location “a” (e.g., “defective” or “non-defective”; “1” or “0” in which “1” indicates defective and “0” indicates non-defective; or other equivalents). The training dataset 425 may include at least some partial datasets.

In operation P603, the training dataset 425 is processed to generate multiple parameter groups 430. For example, if the number of parameters in a complete dataset in the training dataset 425 is n, then the number of parameter groups that may be formed is x=2n−1. For example, if n=4, “15” unique parameter groups may be formed. For example, a first parameter group 430a may correspond to two parameters—“A” and “B” of the complete set of parameters (e.g., A-D), a second parameter group 430b may correspond to three parameters—“B,” “C,” and “D,” a third parameter group 430c may correspond to three parameters—“A,” “B” and “D,” a fourth parameter group may correspond to one parameter—“A” and so on. After identifying the parameter groups 430, each parameter group is populated with data for the corresponding parameters from all the datasets in the training dataset 425 that have data for those parameters. For example, the first parameter group 430a is populated with data for parameters “A” and “B” from all the datasets in the training dataset 425 and the datasets that do not have data for those parameters are deleted from the first parameter group 430a (e.g., dataset 425c).

In operation P605, a sub-model of the defect location prediction model is generated for each parameter group. For example, a first sub-model 405a corresponding to the first parameter group 430a, a second sub-model 405b corresponding to the second parameter group 430b and so on is generated.

In operation P607, each of the sub-models generated in operation P605 is trained with the datasets from the corresponding parameter group. For example, a first sub-model 405a is trained with the datasets (e.g., having values of parameters “A” and “B”) of the first parameter group 430a (e.g., as described at least with reference to FIG. 4). After the first sub-model 405a is trained, it may be used for identifying or predicting defective locations in a new substrate (e.g., a substrate that has not been analyzed using the defect location prediction model 450 yet).

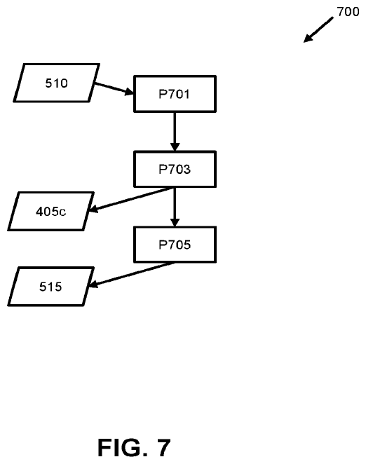

FIG. 7 is a flow diagram of a process 700 for predicting defective locations on a substrate using a single-model prediction mode, consistent with embodiments of the present disclosure. In some embodiments, the process 700 may be implemented in the system 400 of FIG. 4. In operation P701, an input dataset 510 associated with a specified location on a substrate 505 is input to the defect location prediction model 450. For example, the input dataset 510 may include data for process-related parameters “A,” “B” and “D,” which can be metrology data such as CD measurements, aberrations, EPE, or thickness of film, or other such data that may contribute to a defect.

In operation P703, the defect location prediction model 450 selects one of the sub-models based on the process-related parameters available in the input dataset 510. For example, the defect location prediction model 450 may select the third sub-model 405c corresponding to the third parameter group 430c, which includes process-related parameters “A” “B” and “D,” that matches with the process-related parameters of the input dataset 510.

In operation P705, the defect location prediction model 450 executes the selected sub-model to predict a defect for the specified location based on the input dataset 510. For example, the third sub-model 405c is executed with the values “A21” “B21” and “D21” from the input dataset 510 to generate a prediction 515 for the specified location. The prediction 515 may indicate whether the specified location is likely to be defective or non-defective.

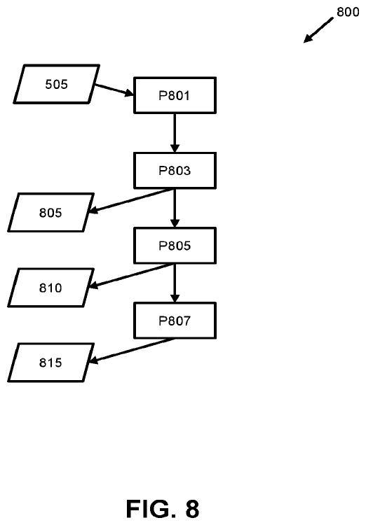

FIG. 8 is a flow diagram of a process 800 for predicting defective locations on a substrate using multi-model prediction mode, consistent with embodiments of the present disclosure. In some embodiments, the process 800 may be implemented in the system 400 of FIG. 4. In operation P801, an input dataset 510 associated with a specified location on a substrate 505 is input to the defect location prediction model 450. For example, the input dataset 510 may include data for process-related parameters “A,” “B” and “D,” which can be metrology data such as CD measurements, aberrations, EPE, or thickness of film, or other such data that may contribute to a defect.

In operation P803, the defect location prediction model 450 selects a set of sub-models 805 corresponding to various combinations of the parameters available in the input dataset 510. For example, the set of sub-models 805 may include a first sub-model 405a corresponding to the first parameter group 430a, which includes parameters “A” and “B,” a third sub-model 405c corresponding to the third parameter group 430c, which includes parameters “A” “B” and “D,” a fourth sub-model 405d corresponding to a fourth parameter group, which includes parameters “B” and “D,” and a fifth sub-model 405x corresponding to a fifth parameter group, which includes parameters “A” and “D” and so on.

In operation P805, the defect location prediction model 450 executes the selected set of sub-models 805 to generate a set of predictions 810. For example, the set of predictions 810 may include a prediction 525a generated by the first sub-model 405a based on the values “A21” and “B21,” a prediction 525b generated by the third sub-model 405c based on the values “A21,” “B21,” and “D21,” a prediction 525c generated by the fourth sub-model 405d based on the values “B21,” and “D21,” and a prediction 525d generated by the fifth sub-model 405x based on the values “A21,” and “D21.”

In operation P807, the set of predictions 810 is input to a second layer model of the defect location prediction model 450 to generate a final prediction 815 (e.g., final prediction 555), which may indicate whether the specified location is likely to be defective or non-defective.

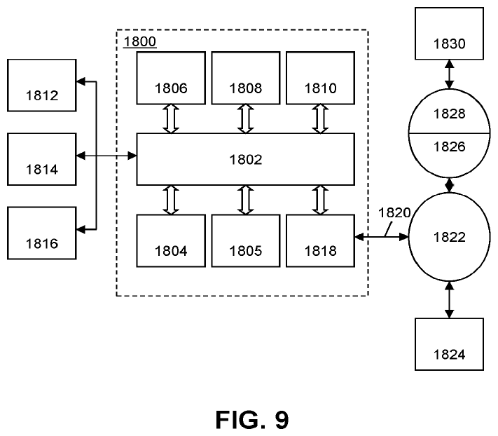

FIG. 9 is a block diagram that illustrates a computer system 1800 which can assist in implementing the methods, flows, modules, components, or the apparatus disclosed herein. Computer system 1800 includes a bus 1802 or other communication mechanism for communicating information, and a processor 1804 (or multiple processors 1804 and 1805) coupled with bus 1802 for processing information. Computer system 1800 also includes a main memory 1806, such as a random-access memory (RAM) or other dynamic storage device, coupled to bus 1802 for storing information and instructions to be executed by processor 1804. Main memory 1806 also may be used for storing temporary variables or other intermediate information during execution of instructions to be executed by processor 1804. Computer system 1800 further includes a read only memory (ROM) 1808 or other static storage device coupled to bus 1802 for storing static information and instructions for processor 1804. A storage device 1810, such as a magnetic disk or optical disk, is provided and coupled to bus 1802 for storing information and instructions.

Computer system 1800 may be coupled via bus 1802 to a display 1812, such as a cathode ray tube (CRT) or flat panel or touch panel display for displaying information to a computer user. An input device 1814, including alphanumeric and other keys, is coupled to bus 1802 for communicating information and command selections to processor 1804. Another type of user input device is cursor control 1816, such as a mouse, a trackball, or cursor direction keys for communicating direction information and command selections to processor 1804 and for controlling cursor movement on display 1812. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 1800 in response to processor 1804 executing one or more sequences of one or more instructions contained in main memory 1806. Such instructions may be read into main memory 1806 from another computer-readable medium, such as storage device 1810. Execution of the sequences of instructions contained in main memory 1806 causes processor 1804 to perform the process steps described herein. One or more processors in a multi-processing arrangement may also be employed to execute the sequences of instructions contained in main memory 1806. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1804 for execution. Such a medium may take many forms, including but not limited to, non-volatile media, volatile media, and transmission media. Non-volatile media include, for example, optical or magnetic disks, such as storage device 1810. Volatile media include dynamic memory, such as main memory 1806. Transmission media include coaxial cables, copper wire and fiber optics, including the wires that comprise bus 1802. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1804 for execution. For example, the instructions may initially be borne on a magnetic disk of a remote computer. The remote computer can load the instructions into its dynamic memory and send the instructions over a telephone line using a modem. A modem local to computer system 1800 can receive the data on the telephone line and use an infrared transmitter to convert the data to an infrared signal. An infrared detector coupled to bus 1802 can receive the data carried in the infrared signal and place the data on bus 1802. Bus 1802 carries the data to main memory 1806, from which processor 1804 retrieves and executes the instructions. The instructions received by main memory 1806 may optionally be stored on storage device 1810 either before or after execution by processor 1804.

Computer system 1800 may also include a communication interface 1818 coupled to bus 1802. Communication interface 1818 provides a two-way data communication coupling to a network link 1820 that is connected to a local network 1822. For example, communication interface 1818 may be an integrated services digital network (ISDN) card or a modem to provide a data communication connection to a corresponding type of telephone line. As another example, communication interface 1818 may be a local area network (LAN) card to provide a data communication connection to a compatible LAN. Wireless links may also be implemented. In any such implementation, communication interface 1818 sends and receives electrical, electromagnetic, or optical signals that carry digital data streams representing various types of information.

Network link 1820 typically provides data communication through one or more networks to other data devices. For example, network link 1820 may provide a connection through local network 1822 to a host computer 1824 or to data equipment operated by an Internet Service Provider (ISP) 1826. ISP 1826 in turn provides data communication services through the worldwide packet data communication network, now commonly referred to as the “Internet” 1828. Local network 1822 and Internet 1828 both use electrical, electromagnetic, or optical signals that carry digital data streams. The signals through the various networks and the signals on network link 1820 and through communication interface 1818, which carry the digital data to and from computer system 1800, are exemplary forms of carrier waves transporting the information.

Computer system 1800 can send messages and receive data, including program code, through the network(s), network link 1820, and communication interface 1818. In the Internet example, a server 1830 might transmit a requested code for an application program through Internet 1828, ISP 1826, local network 1822 and communication interface 1818. One such downloaded application may provide all or part of a method described herein, for example. The received code may be executed by processor 1804 as it is received, and/or stored in storage device 1810, or other non-volatile storage for later execution. In this manner, computer system 1800 may obtain application code in the form of a carrier wave.

A non-transitory computer readable medium may be provided that stores instructions for a processor of a controller (e.g., controller 50 of FIG. 1) to carry out, among other things, image inspection, image acquisition, stage positioning, beam focusing, electric field adjustment, beam bending, condenser lens adjusting, activating charged-particle source, beam deflecting, and at least a portion of the processes. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

Relative dimensions of components in drawings may be exaggerated for clarity. Within the description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

The embodiments may further be described using the following clauses:
1. A non-transitory computer-readable medium having instructions that, when executed by a computer, cause the computer to execute a method for training a defect location prediction model, the method comprising:
   receiving a dataset for each of a set of locations on a set of substrates having data regarding a plurality of process-related parameters, wherein the set of locations comprise locations with partial datasets in which data regarding one or more of the process-related parameters is absent;
   processing the datasets to generate multiple parameter groups having different sets of process-related parameters, wherein each parameter group includes data for each parameter of a corresponding set of process-related parameters; and
   for each parameter group:
      creating a sub-model of the defect location prediction model based on the corresponding set of process-related parameters of the parameter group; and
      training the sub-model by using data from the parameter group.
2. The computer-readable medium of clause 1, wherein training the sub-model is an iterative process in which each iteration includes:
   inputting data from the parameter group to the sub-model to obtain a predicted result from the sub-model, wherein the predicted result of the sub-model is indicative of whether a specified location on a specified substrate is likely to be defective or non-defective;
   determining a cost function based on the predicted result and an actual result that is provided as input associated with the parameter group; and
   adjusting the sub-model based on the cost function.
3. The computer-readable medium of clause 2, wherein the actual result is an inspection result of the specified substrate obtained from an inspection system, the actual result indicative of whether the specified location is defective or non-defective.
4. The computer-readable medium of clause 1 further comprising:
   receiving a first partial dataset for a first location on a first substrate;
   selecting one of the sub-models based on a first set of process-related parameters available in the first partial dataset; and
   executing the selected sub-model to predict a defect for the first location based on the first partial dataset.
5. The computer-readable medium of clause 1 further comprising:
   receiving a first partial dataset for a first location on a first substrate, wherein the first partial dataset includes data for a first set of process-related parameters of the plurality of process-related parameters;
   selecting a set of sub-models, wherein each sub-model of the set corresponds to different parameter subsets of the first set of process-related parameters;
   for each sub-model of the set, executing the sub-model to generate a prediction of a defect for the first location by inputting a portion of the first partial dataset corresponding to parameters of the sub-model; and
   executing an ensemble model to predict a defect for the first location based on the predictions generated by the set of sub-models.
6. The computer-readable medium of clause 5, wherein the ensemble model is trained to predict a defect for a location on a substrate based on an initial dataset that includes predictions generated by the set of sub-models for a number of locations on a number of substrates.
7. The computer-readable medium of clause 1, wherein processing the datasets includes:
   selecting a first set of process-related parameters from the plurality of process-related parameters to generate a first parameter group; and
   populating the first parameter group with data for the first set of process-related parameters from the datasets, wherein the datasets that do not have data for the first set of process-related parameters are excluded.
8. The computer-readable medium of clause 1, wherein training the sub-models includes:
   training a first sub-model corresponding to a first parameter group by inputting data from the first parameter group, the first parameter group including data for a first set of process-related parameters from the datasets; and
   training a second sub-model corresponding to a second parameter group using the first sub-model, wherein the second parameter group includes one or more parameters in addition to the first set of process-related parameters.
9. The computer-readable medium of clause 1, wherein each sub-model includes two or more process-related parameters.
10. The computer-readable medium of clause 1, wherein the process-related parameters include parameters associated with multiple processes involved in forming a pattern on a substrate.
11. The computer-readable medium of clause 10, wherein the parameters include metrology data associated with the multiple processes.
12. A non-transitory computer-readable medium having instructions that, when executed by a computer, cause the computer to execute a method for predicting a defect at a location on a substrate, the method comprising:
   receiving a partial dataset for a location on a substrate, wherein the partial dataset includes data for a subset of a set of process-related parameters;
   selecting a first sub-model from a plurality of sub-models of a defect location prediction model trained to predict a defect associated with the location on the substrate, wherein the first sub-model is selected based on process-related parameters available in the partial dataset; and
   executing the selected sub-model to predict the defect.
13. The computer-readable medium of clause 12, wherein selecting the first sub-model includes:
   selecting one of the sub-models associated with a set of process-related parameters matching the process-related parameters available in the partial dataset as the first sub-model.
14. The computer-readable medium of clause 12, wherein selecting the first sub-model further includes:
   selecting a set of sub-models, wherein each sub-model of the set corresponds to different process-related parameters available in the partial dataset;
   for each sub-model of the set, executing the corresponding sub-model to generate a prediction of a defect for the location by inputting a portion of the partial dataset corresponding to process-related parameters of the sub-model; and
   executing an ensemble model to predict a defect for the location based on the predictions generated by the set of sub-models.
15. The computer-readable medium of clause 14, wherein the ensemble model is trained to predict a defect for a specified location on a specified substrate based on an initial dataset that includes predictions generated by the sub-models for a number of locations on a number of substrates.
16. The computer-readable medium of clause 12, wherein selecting the first sub-model includes:
   training the first sub-model with data from a first parameter group, wherein the first parameter group includes data for the process-related parameters associated with the first sub-model for each of a set of locations on a set of substrates.
17. The computer-readable medium of clause 16, wherein training the first sub-model is an iterative process in which each iteration includes:
   determining a cost function that is indicative of a difference between a predicted result of the first sub-model and an actual result that is provided with the first parameter group; and
   adjusting model parameters of the first sub-model based on the cost function.
18. A method for training a defect location prediction model, the method comprising:
   receiving a dataset for each of a set of locations on a set of substrates having data regarding a plurality of process-related parameters, wherein the set of locations comprise locations with partial datasets in which data regarding one or more of the process-related parameters is absent;
   processing the datasets to generate multiple parameter groups having different sets of process-related parameters, wherein each parameter group includes data for each parameter of a corresponding set of process-related parameters; and
   for each parameter group:
      creating a sub-model of the defect location prediction model based on the corresponding set of process-related parameters of the parameter group; and
      training the sub-model by using data from the parameter group.
19. The method of clause 18, wherein training the sub-model is an iterative process in which each iteration includes:
   inputting data from the parameter group to the sub-model to obtain a predicted result from the sub-model, wherein the predicted result of the sub-model is indicative of whether a specified location on a specified substrate is likely to be defective or non-defective;
   determining a cost function based on the predicted result and an actual result that is provided as input associated with the parameter group; and
   adjusting the sub-model based on the cost function.
20. The method of clause 19, wherein the actual result is an inspection result of the specified substrate obtained from an inspection system, the actual result indicative of whether the specified location is defective or non-defective.
21. The method of clause 18 further comprising:
   receiving a first partial dataset for a first location on a first substrate;
   selecting one of the sub-models based on a first set of process-related parameters available in the first partial dataset; and
   executing the selected sub-model to predict a defect for the first location based on the first partial dataset.
22. The method of clause 18 further comprising:
   receiving a first partial dataset for a first location on a first substrate, wherein the first partial dataset includes data for a first set of process-related parameters of the plurality of process-related parameters;
   selecting a set of sub-models, wherein each sub-model of the set corresponds to different parameter subsets of the first set of process-related parameters;
   for each sub-model of the set, executing the sub-model to generate a prediction of a defect for the first location by inputting a portion of the first partial dataset corresponding to parameters of the sub-model; and
   executing an ensemble model to predict a defect for the first location based on the predictions generated by the set of sub-models.
23. The method of clause 22, wherein the ensemble model is trained to predict a defect for a location on a substrate based on an initial dataset that includes predictions generated by the sub-models for a number of locations on a number of substrates.
24. The method of clause 18, wherein processing the datasets includes:
   selecting a first set of process-related parameters from the plurality of process-related parameters to generate a first parameter group; and
   populating the first parameter group with data for the first set of process-related parameters from the datasets, wherein the datasets that do not have data for the first set of process-related parameters are excluded.
25. The method of clause 18, wherein training the sub-models includes:
   training a first sub-model corresponding to a first parameter group by inputting data from the first parameter group, the first parameter group including data for a first set of process-related parameters from the datasets; and
   training a second sub-model corresponding to a second parameter group using the first sub-model, wherein the second parameter group includes one or more parameters in addition to the first set of process-related parameters.
26. The method of clause 18, wherein each sub-model includes two or more process-related parameters.
27. The method of clause 18, wherein the process-related parameters include parameters associated with multiple processes involved in forming a pattern on a substrate.
28. The method of clause 27, wherein the parameters include metrology data associated with the multiple processes.
29. A method for predicting a defect at a location on a substrate, the method comprising:
   receiving a partial dataset for a location on a substrate, wherein the partial dataset includes data for a subset of a set of process-related parameters;
   selecting a first sub-model from a plurality of sub-models of a defect location prediction model trained to predict a defect associated with the location on the substrate, wherein the first sub-model is selected based on process-related parameters available in the partial dataset; and
   executing the selected sub-model to predict the defect.
30. The method of clause 29, wherein selecting the first sub-model includes:
   selecting one of the sub-models associated with a set of process-related parameters matching the process-related parameters available in the partial dataset as the first sub-model.
31. The method of clause 29, wherein selecting the first sub-model further includes:
   selecting a set of sub-models, wherein each sub-model of the set corresponds to different process-related parameters available in the partial dataset;
   for each sub-model of the set, executing the corresponding sub-model to generate a prediction of a defect for the location by inputting a portion of the partial dataset corresponding to process-related parameters of the sub-model; and
   executing an ensemble model to predict a defect for the location based on the predictions generated by the set of sub-models.
32. The method of clause 31, wherein the ensemble model is trained to predict a defect for a specified location on a specified substrate based on an initial dataset that includes predictions generated by the sub-models for a number of locations on a number of substrates.
33. An apparatus for training a defect location prediction model to predict a defect on a substrate, the apparatus comprising:
   a memory storing a set of instructions; and
   at least one processor configured to execute the set of instructions to cause the apparatus to perform a method of:
      receiving a dataset for each of a set of locations on a set of substrates having data regarding a plurality of process-related parameters, wherein the set of locations comprise locations with partial datasets in which data regarding one or more of the process-related parameters is absent;
      processing the datasets to generate multiple parameter groups having different sets of process-related parameters, wherein each parameter group includes data for each parameter of a corresponding set of process-related parameters; and
      for each parameter group:
         creating a sub-model of the defect location prediction model based on the corresponding set of process-related parameters of the parameter group; and
         training the sub-model by using data from the parameter group.
34. The apparatus of clause 33, wherein training the sub-model is an iterative process in which each iteration includes:
   inputting data from the parameter group to the sub-model to obtain a predicted result from the sub-model, wherein the predicted result of the sub-model is indicative of whether a specified location on a specified substrate is likely to be defective or non-defective;
   determining a cost function based on the predicted result and an actual result that is provided as input associated with the parameter group; and
   adjusting the sub-model based on the cost function.
35. The apparatus of clause 34, wherein the actual result is an inspection result of the specified substrate obtained from an inspection system, the actual result indicative of whether the specified location is defective or non-defective.
36. The apparatus of clause 33, wherein the method further comprises:
   receiving a first partial dataset for a first location on a first substrate;
   selecting one of the sub-models based on a first set of process-related parameters available in the first partial dataset; and
   executing the selected sub-model to predict a defect for the first location based on the first partial dataset.
37. The apparatus of clause 33, wherein the method further comprises:
   receiving a first partial dataset for a first location on a first substrate, wherein the first partial dataset includes data for a first set of process-related parameters of the plurality of process-related parameters;
   selecting a set of sub-models, wherein each sub-model of the set corresponds to different parameter subsets of the first set of process-related parameters;
   for each sub-model of the set, executing the sub-model to generate a prediction of a defect for the first location by inputting a portion of the first partial dataset corresponding to parameters of the sub-model; and
   executing an ensemble model to predict a defect for the first location based on the predictions generated by the set of sub-models.
38. The apparatus of clause 37, wherein the ensemble model is trained to predict a defect for a location on a substrate based on an initial dataset that includes predictions generated by the set of sub-models for a number of locations on a number of substrates.
39. A non-transitory computer-readable medium having instructions recorded thereon, the instructions when executed by a computer implementing the method of any of the above clauses.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A non-transitory computer-readable medium having instructions that, when executed by a computer, cause the computer to execute a method for training a defect location prediction model, the method comprising:
receiving a dataset for each of a set of locations on a set of substrates having data regarding a plurality of process-related parameters, wherein the set of locations comprise locations with partial datasets in which data regarding one or more of the process-related parameters is absent;
processing the datasets to generate multiple parameter groups having different sets of process-related parameters, wherein each parameter group includes data for each parameter of a corresponding set of process-related parameters; and
for each parameter group:
creating a sub-model of the defect location prediction model based on the corresponding set of process-related parameters of the parameter group; and
training the sub-model by using data from the parameter group.

2. The computer-readable medium of claim 1, wherein training the sub-model is an iterative process in which each iteration includes:
inputting data from the parameter group to the sub-model to obtain a predicted result from the sub-model, wherein the predicted result of the sub-model is indicative of whether a specified location on a specified substrate is likely to be defective or non-defective;
determining a cost function based on the predicted result and an actual result that is provided as input associated with the parameter group; and
adjusting the sub-model based on the cost function.

3. The computer-readable medium of claim 2, wherein the actual result is an inspection result of the specified substrate obtained from an inspection system, the actual result indicative of whether the specified location is defective or non-defective.

4. The computer-readable medium of claim 1 further comprising:
receiving a first partial dataset for a first location on a first substrate;
selecting one of the sub-models based on a first set of process-related parameters available in the first partial dataset; and
executing the selected sub-model to predict a defect for the first location based on the first partial dataset.

5. The computer-readable medium of claim 1 further comprising:
receiving a first partial dataset for a first location on a first substrate, wherein the first partial dataset includes data for a first set of process-related parameters of the plurality of process-related parameters;
selecting a set of sub-models, wherein each sub-model of the set corresponds to different parameter subsets of the first set of process-related parameters;
for each sub-model of the set, executing the sub-model to generate a prediction of a defect for the first location by inputting a portion of the first partial dataset corresponding to parameters of the sub-model; and
executing an ensemble model to predict a defect for the first location based on the predictions generated by the set of sub-models.

6. The computer-readable medium of claim 5, wherein the ensemble model is trained to predict a defect for a location on a substrate based on an initial dataset that includes predictions generated by the set of sub-models for a number of locations on a number of substrates.

7. The computer-readable medium of claim 1, wherein processing the datasets includes:
selecting a first set of process-related parameters from the plurality of process-related parameters to generate a first parameter group; and
populating the first parameter group with data for the first set of process-related parameters from the datasets, wherein the datasets that do not have data for the first set of process-related parameters are excluded.

8. The computer-readable medium of claim 1, wherein training the sub-models includes:
training a first sub-model corresponding to a first parameter group by inputting data from the first parameter group, the first parameter group including data for a first set of process-related parameters from the datasets; and
training a second sub-model corresponding to a second parameter group using the first sub-model, wherein the second parameter group includes one or more parameters in addition to the first set of process-related parameters.

9. The computer-readable medium of claim 1, wherein each sub-model includes two or more process-related parameters.

10. The computer-readable medium of claim 1, wherein the process-related parameters include parameters associated with multiple processes involved in forming a pattern on a substrate.

11. The computer-readable medium of claim 10, wherein the parameters include metrology data associated with the multiple processes.

12. A non-transitory computer-readable medium having instructions that, when executed by a computer, cause the computer to execute a method for predicting a defect at a location on a substrate, the method comprising:
receiving a partial dataset for a location on a substrate, wherein the partial dataset includes data for a subset of a set of process-related parameters;
selecting a first sub-model from a plurality of sub-models of a defect location prediction model trained to predict a defect associated with the location on the substrate, wherein the first sub-model is selected based on process-related parameters available in the partial dataset; and
executing the selected sub-model to predict the defect.

13. The computer-readable medium of claim 12, wherein selecting the first sub-model includes:
selecting one of the sub-models associated with a set of process-related parameters matching the process-related parameters available in the partial dataset as the first sub-model.

14. The computer-readable medium of claim 12, wherein selecting the first sub-model further includes:
selecting a set of sub-models, wherein each sub-model of the set corresponds to different process-related parameters available in the partial dataset;
for each sub-model of the set, executing the corresponding sub-model to generate a prediction of a defect for the location by inputting a portion of the partial dataset corresponding to process-related parameters of the sub-model; and
executing an ensemble model to predict a defect for the location based on the predictions generated by the set of sub-models.

15. The computer-readable medium of claim 14, wherein the ensemble model is trained to predict a defect for a specified location on a specified substrate based on an initial dataset that includes predictions generated by the sub-models for a number of locations on a number of substrates.

16. An apparatus for training a defect location prediction model to predict a defect on a substrate, the apparatus comprising:
a memory storing a set of instructions; and
at least one processor configured to execute the set of instructions to cause the apparatus to perform operations comprising:
receiving a dataset for each of a set of locations on a set of substrates having data regarding a plurality of process-related parameters, wherein the set of locations comprise locations with partial datasets in which data regarding one or more of the process-related parameters is absent;
processing the datasets to generate multiple parameter groups having different sets of process-related parameters, wherein each parameter group includes data for each parameter of a corresponding set of process-related parameters; and
for each parameter group:
creating a sub-model of the defect location prediction model based on the corresponding set of process-related parameters of the parameter group; and
training the sub-model by using data from the parameter group.

17. The apparatus of claim 16, wherein training the sub-model is an iterative process in which each iteration includes:
inputting data from the parameter group to the sub-model to obtain a predicted result from the sub-model, wherein the predicted result of the sub-model is indicative of whether a specified location on a specified substrate is likely to be defective or non-defective;
determining a cost function based on the predicted result and an actual result that is provided as input associated with the parameter group; and
adjusting the sub-model based on the cost function.

18. The apparatus of claim 17, wherein the actual result is an inspection result of the specified substrate obtained from an inspection system, the actual result indicative of whether the specified location is defective or non-defective.

19. The apparatus of claim 16, wherein the operations further comprise:
receiving a first partial dataset for a first location on a first substrate;
selecting one of the sub-models based on a first set of process-related parameters available in the first partial dataset; and
executing the selected sub-model to predict a defect for the first location based on the first partial dataset.

20. The apparatus of claim 16, wherein the operations further comprise:
receiving a first partial dataset for a first location on a first substrate, wherein the first partial dataset includes data for a first set of process-related parameters of the plurality of process-related parameters;
selecting a set of sub-models, wherein each sub-model of the set corresponds to different parameter subsets of the first set of process-related parameters;
for each sub-model of the set, executing the sub-model to generate a prediction of a defect for the first location by inputting a portion of the first partial dataset corresponding to parameters of the sub-model; and
executing an ensemble model to predict a defect for the first location based on the predictions generated by the set of sub-models.
